(19) United States
(12) Patent Application Publication
(10) Pub. No.: US 2025/0226561 A1
(43) Pub. Date: Jul. 10, 2025

(54) MICROSTRIP BOARD GROUND PLANE IMPEDANCE MATCHING ADJUSTMENT

(71) Applicant: MACOM Technology Solutions Holdings, Inc., Lowell, MA (US)

(72) Inventor: Benone Achiriloaie, Riverside, CA (US)

(21) Appl. No.: 18/853,659

(22) PCT Filed: Apr. 10, 2023
(86) PCT No.: PCT/US2023/065580

§ 371 Date: Oct. 2, 2024

Related U.S. Application Data
(60) Provisional application No. 63/365,655, filed on Jun. 1, 2022.

(51) Int. Cl. H01P 1/30; H01P 3/08; H05K 1/02

(52) U.S. Cl. CPC H01P 1/30; H01P 3/08; H05K 1/0201; H05K 1/0218; H05K 2201/066

(57) ABSTRACT

Microstrip technology boards including microstrip traces matched over a range of different impedances are described. The microstrip boards include impedance-offset openings in ground planes under certain microstrip traces. The openings result in different effective dielectric constants and higher impedances for microstrip traces aligned with the openings, as compared to microstrip traces aligned over metal ground planes. The microstrip boards can also be mounted to conductive heatsinks. The conductive heatsinks act as ground planes for the microstrip traces aligned with the impedance-offset ground plane openings. The conductive heatsinks can include depressions co-located with the ground plane openings. Impedances of microstrip traces aligned with the ground plane openings are thus a function of the dielectric constant of the central core of the boards, the thickness of the central core, and the thickness of the air gap provided by the heatsink depressions.

### CROSS-REFERENCE TO RELATED APPLICATIONS

This application claims the benefit of and priority to U.S. Provisional Patent Application No. 63/365,655, filed Jun. 1, 2022, the entire contents of which is hereby incorporated herein by reference.

### BACKGROUND

In the field of radio frequency (RF) amplifiers, an RF pallet is an amplifier module including one or more semiconductor amplifiers arranged together with other components on a board. Pallets can support input matching networks for impedance matching, phase matching, and other purposes, RF couplers and splitters, impedance transformation networks, output matching networks, power feeds, input connectors, output connectors, and other components. Pallets can be mounted on an aluminum or copper heatsink. A number of design concerns are particular to pallets due to the unique and focused purpose of pallets for RF amplification.

### SUMMARY

Microstrip technology boards including microstrip traces matched over a range of different impedances are described. The microstrip boards include impedance-offset openings in ground planes under certain microstrip traces. The openings result in different effective dielectric constants and higher impedances for microstrip traces aligned with the openings, as compared to microstrip traces aligned over metal ground planes. The microstrip boards can also be mounted to conductive heatsinks. The conductive heatsinks act as ground planes for the microstrip traces aligned with the impedance-offset ground plane openings. The conductive heatsinks can include depressions co-located with the ground plane openings. Impedances of microstrip traces aligned with the ground plane openings are thus a function of the dielectric constant of the central core of the boards, the thickness of the central core, and the thickness of the air gap provided by the heatsink depressions.

In one example, a microstrip board assembly includes a conductive heatsink and a microstrip board mounted to the conductive heatsink. The microstrip board includes a central core of dielectric material having a dielectric constant, a first microstrip trace on one side of the central core, a second microstrip trace on the one side of the central core, and a ground plane formed on another side of the central core, the ground plane extending under the second microstrip trace and comprising an impedance-offset opening under the first microstrip trace.

The first microstrip trace and the second microstrip trace have the same dimensions and electrical path, including the same width, length, thickness, and path. The central core of dielectric material has the same thickness and dielectric constant across the microstrip board. Having the same dimensions and electrical path, the first microstrip trace has a first impedance, and the second microstrip trace has a second impedance different than the first impedance.

In other aspects, the ground plane contacts and is electrically coupled to a top surface of the conductive heatsink. The assembly has an effective dielectric constant between the first microstrip trace and ground that is different than the dielectric constant of the central core, and the effective dielectric constant is a combination of the dielectric constant of the central core and a second dielectric constant of an air gap.

In other aspects, the conductive heatsink includes an impedance-offset depression under the first microstrip trace. The impedance-offset depression provides an air gap under the first microstrip trace. In some cases, the microstrip board includes a core depression within the impedance-offset opening under the first microstrip trace. The core depression provides another air gap under the first microstrip trace. In other aspects, the ground plane includes the impedance-offset opening under the first microstrip trace, and the conductive heatsink includes an impedance-offset depression under the first microstrip trace.

In another example, a microstrip board includes a central core of dielectric material having a dielectric constant, a first microstrip trace on one side of the central core, a second microstrip trace on the one side of the central core, and a ground plane formed on another side of the central core. The ground plane extends under the second microstrip trace and includes an impedance-offset opening under the first microstrip trace. In one case, the ground plane extends under a first portion of the first microstrip trace and the impedance-offset opening extends under a second portion the first microstrip trace.

The first microstrip trace and the second microstrip trace have the same dimensions and electrical path, including the same width, length, thickness, and path. The central core of dielectric material has the same thickness and dielectric constant across the microstrip board. Having the same dimensions and electrical path, the first microstrip trace has a first impedance, and the second microstrip trace has a second impedance different than the first impedance.

The microstrip board can be mounted to a conductive heatsink in some cases. The conductive heatsink includes an impedance-offset depression under the first microstrip trace, and the impedance-offset depression provides an air gap under the first microstrip trace.

In another example, a microstrip board assembly includes a conductive heatsink and a microstrip board mounted to the conductive heatsink. The microstrip board includes a central core of dielectric material having a dielectric constant, a microstrip trace on one side of the central core, and a ground plane formed on another side of the central core, the ground plane comprising an impedance-offset opening under the microstrip trace. The ground plane contacts and is electrically coupled to a top surface of the conductive heatsink.

In one aspect, the assembly includes an effective dielectric constant between the microstrip trace and ground that is different than the dielectric constant of the central core, and the effective dielectric constant is a combination of the dielectric constant of the central core and a second dielectric constant of an air gap. In other aspects, the conductive heatsink includes an impedance-offset depression under the microstrip trace. The impedance-offset depression provides an air gap under the microstrip trace. In other aspects, the microstrip board includes a core depression within the impedance-offset opening under the microstrip trace. The core depression provides an air gap under the microstrip trace.

### BRIEF DESCRIPTION OF THE DRAWINGS

Aspects of the present disclosure can be better understood with reference to the following drawings. It is noted that the elements in the drawings are not necessarily drawn to scale, with emphasis instead being placed upon illustrating the principles of the examples. In the drawings, like reference numerals designate like or corresponding, but not necessarily the same, elements throughout the several views.

FIG. 1 illustrates an assembly for microwave signal amplification according to various examples described herein.

FIG. 2 illustrates the top of a microstrip board according to various examples described herein.

FIG. 3 illustrates the bottom of a microstrip board according to various examples described herein.

FIG. 4 illustrates the top of a conductive heatsink according to various examples described herein.

FIG. 5 illustrates examples of microstrip traces having different impedances according to various examples described herein.

FIG. 6A illustrates the cross-sectional view designated A-A in FIG. 5 according to various examples described herein.

FIG. 6B illustrates the cross-sectional view designated B-B in FIG. 5 according to various examples described herein.

FIG. 6C illustrates the cross-sectional view designated C-C in FIG. 5 according to various examples described herein.

FIG. 7 illustrates additional examples of microstrip traces having different impedances according to various examples described herein.

FIG. 8 illustrates the cross-sectional view designated D-D in FIG. 7 according to various examples described herein.

### DETAILED DESCRIPTION

An RF pallet is an amplifier module for the amplification of microwave signals. RF pallets can support input matching networks for input impedance matching, phase matching, and other purposes, RF couplers and splitters, impedance transformation networks, output matching networks, power feeds, input connectors, output connectors, and other components. RF pallets support a range of applications including the amplification of microwave signals. As an example, pallet amplifiers support high power microwave signal amplification, such as amplification in the range of 100 to 1000 Watts of microwave signals in the S Band, between 2 to 4 GHz, although the applications for pallet amplifiers are not limited to any particular range of power or frequency band.

RF pallets can incorporate microstrip technology. Microstrip technology relies upon conductive traces fabricated on dielectric material substrates with ground planes. Microstrip components, such as transmission lines, antennas, couplers, filters, power dividers, and other components, can be formed using microstrip technology. The microstrip components can be implemented using metallization patterns formed on one side of a central core of dielectric material, with a ground plane on the other side of the central core.

Typical substrate materials for microstrips solutions include alumina, silicon, and polytetrafluoroethylene (PTFE) materials, among others. Glass-reinforced epoxy laminate (e.g., FR4 laminate) is a common material in printed circuit boards (PCBs), but a range of other dielectric materials can be relied upon to support microstrip transmission lines. The dielectric constant (Dk) of a vacuum is 1.0, and air has a slightly higher Dk than that of a vacuum and is often modeled to be the same as that of a vacuum. PTFE has a dielectric constant of about 2.0. Materials such as PTFE can be used for RF microwave circuits. However, a range of materials having higher Dk values are available for high-frequency circuit designs, and materials having Dk values ranging from 2.0 to above 10.0 are available and commonly selected for use in microstrip solutions.

Microstrip transmission lines, as one example, can be miniaturized and integrated with other microwave devices on substrates. Microstrip transmission lines can be implemented using metal traces that extend over a first surface of a substrate or PCB, with a ground plane extending over a second, opposite outer surface of the PCB. Some physical characteristics of microstrip transmission lines include strip width, strip length, strip thickness, substrate height, and substrate dielectric constant. Electrical parameters of microstrip transmission lines include characteristic impedance, guide wavelength, and attenuation constant, among others.

According to aspects of the embodiments, RF pallets and other microstrip boards including microstrip traces are described. The microstrip traces allow for impedance matching over a wide range of different impedances. Microstrip boards according to the embodiments can include one or more impedance-offset openings in a ground plane under certain microstrip traces. The openings result in variations of the effective dielectric constants and higher impedances for microstrip traces aligned with (e.g., aligned over) the openings, as compared to microstrip traces aligned over metal ground planes.

The microstrip boards can also be mounted to conductive heatsinks. The conductive heatsinks also act as ground planes for the microstrip traces aligned with the impedance-offset ground plane openings. The conductive heatsinks can include depressions or depressed air gaps. The depressions can be co-located with the ground plane openings in some cases. Impedances of microstrip traces aligned with the ground plane openings are thus a function of the dielectric constant of the central core of the microstrip board, the thickness of the central core, and the size or thickness of the air gap provided by the depressions of the heatsink to which the board is mounted. Where the ground plane openings and air gaps are co-located or aligned, a combination of the dielectric of the central core and that of the air gap represents an effective dielectric constant. By forming the impedance-offset openings in the ground plane and varying the depth of depressions in the heatsink, a range of different effective dielectric constants can be achieved.

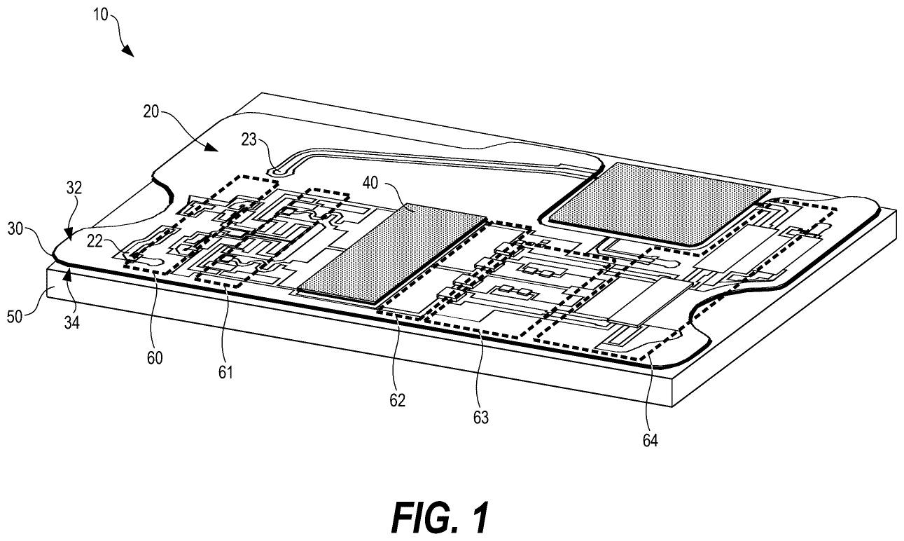

Turning to the drawings, FIG. 1 illustrates an assembly 10 for microwave signal amplification according to various examples described herein. Among other components, the assembly 10 includes a microstrip board 20 and a heatsink 50. The microstrip board 20 is mounted over the heatsink 50, as in the example shown, using threaded screws, bolts, or other mechanical fasteners. The assembly 10 is illustrated as a representative example of a module for the amplification of RF signals. The illustration in FIG. 1 is not exhaustive, and the assembly 10 can include other components that are not illustrated in FIG. 1. Additionally, one or more components shown in FIG. 1 can be omitted in some cases.

The microstrip board 20 (also “board 20”) can be relied upon to implement an RF pallet for the amplification of microwave signals. The board 20 includes a central core 30 of dielectric material, metal layers on the top and bottom surfaces of the central core 30, and a number of active and passive electrical components that are electrically coupled to and interconnected by the board 20. The board 20 is illustrated in a largely unpopulated state (i.e., without components mounted and connected thereto) in FIG. 1, although the power amplifier 40 and certain capacitors, couplers, and other components are illustrated on the board 20. A variety of components can be electrically coupled and interconnected to the board 20, including power transistors, capacitors, resistors, RF splitters, RF couplers, integrated circuits, input connectors, output connectors, and other components, as would be common for RF pallets. The board 20 includes a number of microstrips or microstrip features, such as transmission lines, inductors, and other metal features that act as electrical components together with the other components mounted to the board 20.

The power amplifier 40 can be embodied as one or more high power, group III-V active semiconductor devices, such as power transistors formed from gallium nitride materials, including gallium nitride (GaN) on a silicon carbide (SiC) substrate in one example. The power amplifier 40 can also be embodied as other types of power transistors, including GaN on a silicon (Si) substrate and other group III-V active semiconductor devices. The type and size of the power amplifier 40 can be selected for the desired power handling capability of the assembly 10 and other factors. The concepts of ground plane impedance matching adjustments described herein are not limited to use with certain amplifiers, however, as the concepts can be relied upon to tailor the impedances of microstrip traces regardless of the amplifiers and other active components used.

The board 20 can be embodied as a PCB including metal layers formed or otherwise positioned on outer surfaces of a central core 30 of dielectric material. The central core 30 can be embodied as a PTFE laminate, ceramic-filled PTFE laminate, glass microfiber reinforced PTFE laminate, and other laminate materials. Example laminate materials include the RO3000™ series laminates (e.g., RO3003™, RO3006™, RO3010™, RO3035™, etc.), the RO4000™ series laminates, the RT/duroid® 5000 series laminates, the RT/duroid® 6000 series laminates, and related laminates of Rogers Corporation. The central core 30 is not limited to any particular type or supplier or dielectric or dielectric laminate materials, however. A range of core materials having different Dk values are available for high-frequency circuit designs, and materials having Dk values ranging from 2.0 to above 11.0 are available and commonly selected for use in microstrip solutions. As examples, RO3006™ has a Dk of 6.5, RT/duroid® 6006 has a Dk of 10.2, and RO3010™ has a Dk of 11.

The laminate material of the board 20 can be selected based on the amplification application of the assembly 10. Example applications for the assembly 10 include the power amplification of RF input signals with output power in the range of 100 to 1000 Watts, at frequency ranges between 2.5 to 3.5 GHz, although other power levels and frequency ranges are within the scope of the embodiments.

Among other characteristics, the central core 30 of the board 20 can have a dielectric coefficient suitable for high operating frequencies, a low temperature coefficient of dielectric constant, a stable dielectric constant over a wide frequency range, a thermal coefficient of expansion similar to that of copper, and other preferred characteristics. A thickness of the central core 30 can range from between 5 and 40 mils (i.e., thousandths of an inch) including all increments of 0.5 mils between 5 and 40 mils, although other thicknesses can be relied upon. In one example described below, the central core 30 can have a Dk of 6.5 with a thickness of 10 mils. In other examples, the central core 30 can have a Dk of between 2 and 8, including all Dk values between 2 and 8 in increments of 0.1. Other Dk values and thicknesses can be relied upon.

The board 20 includes a first side 32 or surface (also “top” side or surface) of the central core 30 and an opposite second side 34 or surface (also “bottom” side or surface) of the central core 30. In one example, the board 20 also includes a first metal layer on the first side 32 and a second metal layer on the second side 34 of the central core 30. The first and second metal layers can be formed from copper in one example, and the metal layers can also be formed from aluminum, tin, nickel, other suitable metals, and combinations thereof.

The first or top metal layer of the board 20 is patterned, segmented, or otherwise divided into electrically separated metal traces for the interconnection of certain components mounted to the board 20. The top metal layer of the board 20 can be formed or segmented into one or more microstrip transmission lines, inductors, and other features. The second or bottom metal layer on the second side 34 of the board 20 provides a ground plane for the board 20 and for the microstrip features of the top metal layer.

The second metal layer can extend over a region of the second side 34 of the central core 30. The second metal layer can be relied upon as a ground plane for the board 20 for microstrip implementations. As described below, the second metal layer can include impedance-offset openings (e.g., apertures, voids, or other openings in the second metal layer). The openings result in different effective dielectric constants and higher impedances for microstrip traces that are aligned with the openings, as compared to microstrip traces aligned over metal ground planes.

According to aspects of the embodiments, the board 20 incorporates microstrip traces and features that are individually matched to different impedances. The range of impedances supported by the microstrip traces on the board 20 is relatively large according to the embodiments, and the board 20 includes transitions among the different impedances using only a single, common central core 30 of dielectric material.

As examples of the impedance transitions on the board 20, the power amplifier 40 can have an output impedance of about 2Ω. However, an input 22 and an output 23 of the board 20 can be impedance matched to 50Ω for interfacing with other RF systems. The board 20 includes regions 60-64 of microstrip traces between the input 22 and the output 23 of the board 20. The regions 60 and 61 are on the input side of the power amplifier 40, and the regions 62-64 are on the output side of the power amplifier 40. Thus, the impedances at various circuit nodes and points on the microstrip traces of the board 20 will range over the board 20, such as from 2-50Ω or more.

In the design of the assembly 10, it can be important to account for the impedance transitions from the input 22, through the power amplifier 40, and to the output 23 of the board 20. The regions 60 and 61 can transition in impedance from about 50Ω matching for the input 23, to a different impedance for the input of the power amplifier 40. The regions 62-64 can transition in impedance from about 2Ω for the output of the power amplifier 40 at the region 62, to an intermediate impedance ranging from 5-20Ω, for example, over region 63, to an impedance matched to 50Ω for the region 64 and output 23. Proper impedance matching among the components and the microstrip traces on the board 20 results in improved linear amplification over a range of power and operating frequencies, improved efficiency, improved operating bandwidth, and the improvement of other characteristics for the assembly 10, as understood in the field.

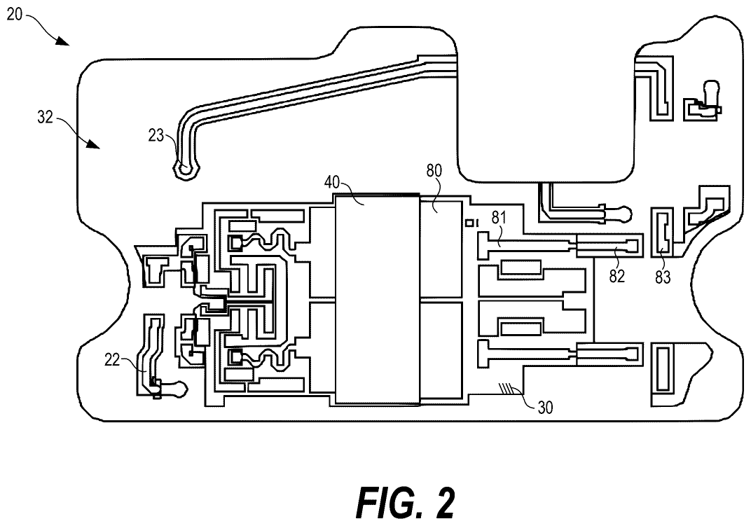

FIG. 2 illustrates the top of the microstrip board 20 according to various examples described herein. The heatsink 50 is omitted from view in FIG. 2. The top metal layer of the board 20 is absent or omitted over some regions, and the central core 30 of the board 20 is referenced in one region in FIG. 2. The top metal layer of the board 20 is patterned, segmented, or otherwise divided into electrically separated metal traces for the interconnection of certain components mounted to the board 20. The top metal layer of the board 20 is thus segmented into one or more microstrip traces, transmission lines, inductors, and other features. Among other microstrip traces, the microstrip board 20 includes microstrip traces 80-83. In one example, the microstrip trace 80 presents an impedance of 2Ω, the microstrip trace 81 presents an impedance between 5-20Ω, and the microstrip trace 83 presents an impedance of 50Ω.

The impedance of the microstrip trace 80 is a function or factor of the dimensions (e.g., width, length, shape) of the trace 80, the thickness of the trace 80, the dielectric constant of the central core 30, the thickness of the central core 30, and other factors. The impedances of the microstrip traces 81-83, among others on the board 20, are also determined based on similar characteristics. Overall, the factors operate as constraints in the ability to accommodate a wide range of impedances for different microstrip traces over the board 20. For example, while it may be possible to design the microstrip trace 80 with dimensions for an impedance of 2Ω (e.g., for matching with the power amplifier 40) at a certain operating frequency using a central core 30 having a Dk of 6.5 and thickness of 10 mils, it may not be possible to design the microstrip trace 82 with suitable dimensions for an impedance of 50Ω using the same central core 30. Instead, the dimensions of the microstrip trace 82 may become too small (e.g., too narrow or thin) at an impedance of 50Ω. Particularly, the dimensions of the microstrip trace 82 may become too small for the power handling requirements of the board 20 at an impedance of 50Ω.

It can also be relatively difficult and costly to manufacture the microstrip board 20 to include two or more dielectric materials of different Dk values in the central core 30, different thicknesses for the central core 30, different metal layer thicknesses for the same metal layer (i.e., different thicknesses of the microstrip traces 81 and 82, for example), or to use separated boards of different dielectric materials to implement the assembly 10. In view of these constraints and concerns, the embodiments described herein incorporate new techniques for impedance matching in microstrip boards and amplifier modules implemented on microstrip boards. The techniques can be relied upon to design the board 20 with microstrip traces 80-83 having a relatively wide range of impedances, while also permitting the traces to be dimensioned in a suitable way to meet the power handling specifications of the assembly 10. The techniques can be extended and relied upon to solve a range of problems facing design engineers of RF pallets.

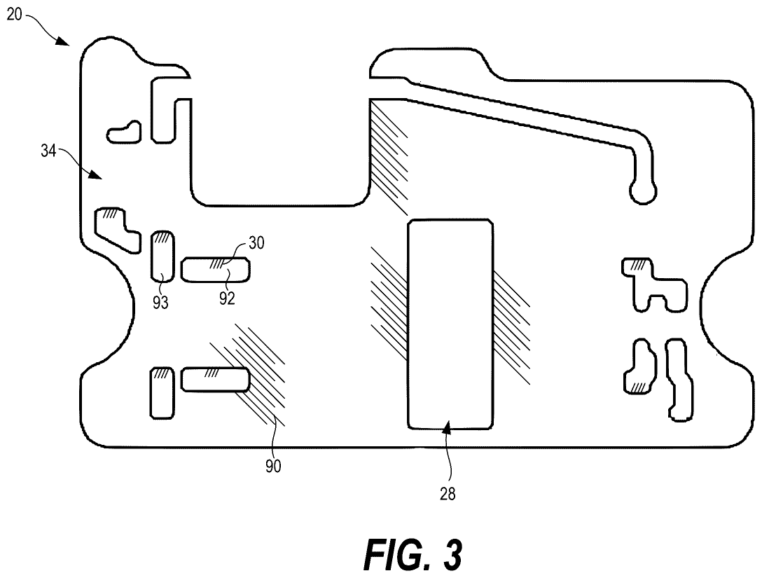

FIG. 3 illustrates the bottom of the microstrip board 20 according to various examples described herein. The power amplifier 40 is omitted from view in FIG. 3. The board 20 includes an aperture, through hole, or opening 28, among possibly others, that extends through from the top side 32 to the bottom side 34 of the board 20. The power amplifier 40 can be mounted within the opening 28 for thermal contact with the heatsink 50.

The board 20 includes a ground plane 90 on the bottom side 34. The ground plane 90 includes a number of impedance-offset openings or apertures, including openings 92 and 93, among others. The openings 92 and 93 are areas in which the metal of the ground plane 90 is omitted. Thus, the bottom surface of the central core 30 is shown through the openings 92 and 93. The positions of the openings 92 and 93 and other openings on the bottom of the board 20 are illustrated as representative examples in FIG. 3. In other cases, the openings can be positioned at other locations. The openings can also vary in size and shape as compared to those shown.

The openings 92 and 93 are positioned under and aligned with the microstrip traces 82 and 83 on the top of the board 20. That is, if the outline of the openings 92 and 93 were projected directly through the central core 30 and the page in FIG. 3, the outline would surround or encompass the microstrip traces 82 and 83 on the top of the board 20. Thus, the openings 92 and 93 are larger than the traces 82 and 83. The omission of the ground plane 90 within the openings 92 and 93, among other locations, impacts the impedances of the microstrip traces 82 and 83. The omission of the ground plane 90 within the openings 92 and 93 tends to higher impedances for the microstrip traces 82 and 83, as compared to if the ground plane 90 was present below the microstrip traces 82 and 83. The board 20 can also include other openings in the ground plane 90 that are aligned with other microstrip traces on the top of the board 20.

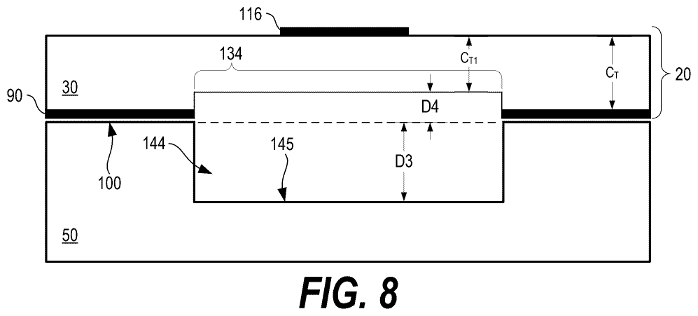

In some cases, the material of the central core 30 can be removed or recessed away, by milling, etching, or other techniques within one or both of the openings 92 and 93. In that case, the thickness of the central core 30 can be thinner within one or both of the openings 92 and 93, among others in the board 20. Examples of the removal of some of the material of the central core 30 within a region of the board 20 are described below with reference to FIG. 8.

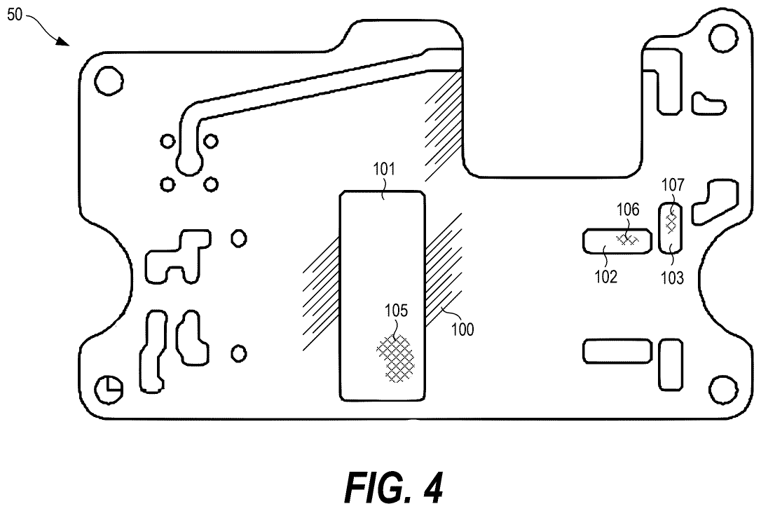

FIG. 4 illustrates the top of the conductive heatsink 50 (also “heatsink 50”) according to various examples described herein. The heatsink 50 can be embodied as a copper or aluminum heatsink, although the heatsink 50 can be formed from other materials. The top surface 100 of the heatsink 50 can be planar, and the ground plane 90 of the board 20 can also be planar. When assembled with the board 20, regions of the ground plane 90 of the board 20 can contact and electrically couple with regions on the top surface 100 of the heatsink 50.

The heatsink 50 also includes a number of depressions 101-103, among others. The positions of the depressions 101-103 are illustrated as representative examples in FIG. 4. In other cases, the depressions can be positioned at other locations, and the heatsink 50 can include additional or fewer depressions as compared to the example shown. The depressions can also vary in size and shape as compared to those shown.

The depressions 101-103 are areas in which the material of the heatsink 50 has been removed or recessed down, by milling, etching, or other techniques. Thus, the surface 105 within the depression 101 is recessed down into the heatsink 50 from the top surface 100 of the heatsink 50. Similarly, the surface 106 within the depression 102 is recessed down into the heatsink 50 from the top surface 100 of the heatsink 50. The surface 107 within the depression 103 is also recessed down into the heatsink 50 from the top surface 100 of the heatsink 50. The surfaces 105-107 can be planar, to the extent possible using the milling, etching, or other techniques used to form them.

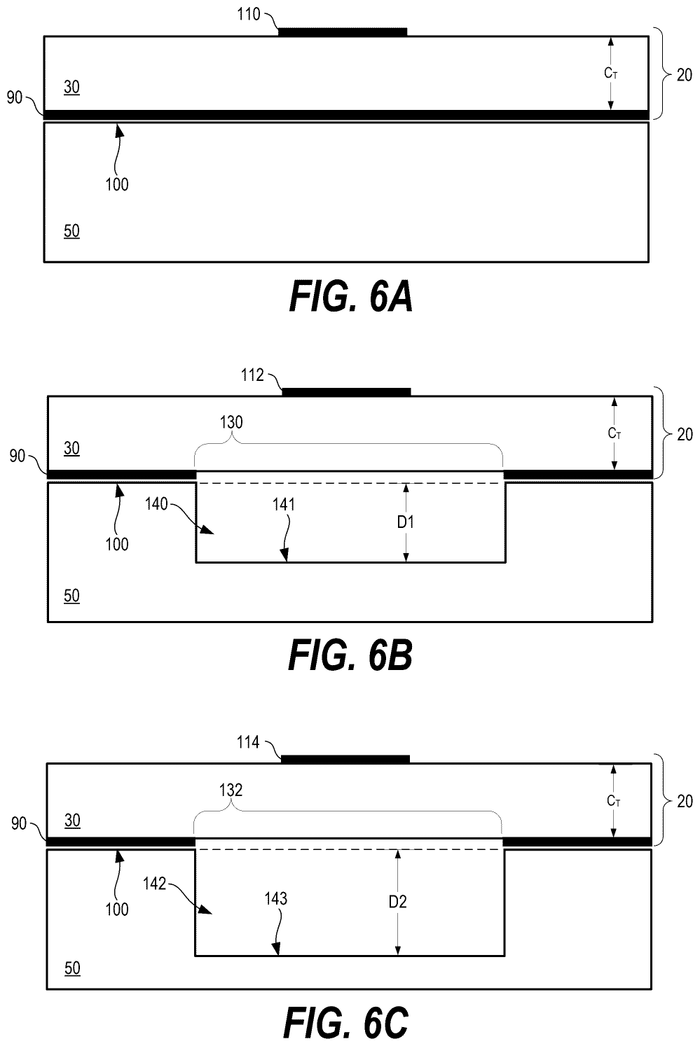

The depression 101 can be formed for the power amplifier 40 to a depth of between 35-50 mils from the top surface 100 of the heatsink 50. That is, the distance between the top surface 100 of the heatsink 50 to the top of the surface 105 within the depression 101 can be between 35-50 mils. The depressions 102 and 103, among others, are formed as impedance-offset depressions. The depressions 102 and 103 can be formed to a depth of between 1-15 mils±0.5 mils from the top surface 100 of the heatsink 50. Other depths for the depressions 102 and 103 are within the scope of the embodiments. Other examples of depressions that can be formed in the heatsink 50 are described below with reference to FIGS. 6A-6C and 8A-8C.

The depressions 102 and 103 in the heatsink 150 are positioned, respectively, to be aligned with the microstrip traces 82 and 83 and the openings 92 and 93 of the board 20. As the ground plane 90 is removed or omitted from within the openings 92 and 93, the top surface 100 of the heatsink 50 effectively acts as a substitute for the ground plane 90 under the microstrip traces 82 and 83. However, the top surface 100 of the heatsink 50 is effectively lowered within the depressions 102 and 103 to the surfaces 106 and 107, respectively. Thus, the depth to which the depressions 102 and 103, among others, are formed impacts the impedances of the microstrip traces 82 and 83, as further described below.

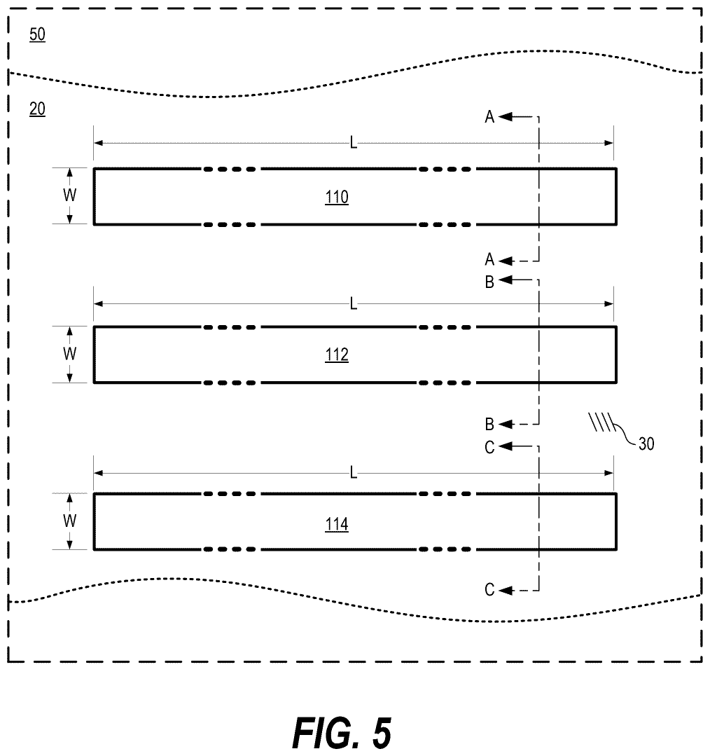

To further explain the concepts described herein, FIG. 5 illustrates example microstrip traces 110, 112, and 114 having different impedances. The traces 110, 112, and 114 can be formed on the board 20, which is positioned on and over the heatsink 50. The traces 110, 112, and 114 have the same dimensions in the example shown, including the same width W, length L, and thickness (i.e., as measured into the page). The central core 30 of the board 20 also has the same Dk and thickness (i.e., thickness D in FIGS. 6A-6C) of dielectric material for all the traces 110, 112, and 114. However, for the same signal of a common frequency, the traces 110, 112, and 114 can present different impedances according to the concepts described herein.

FIG. 6A illustrates the cross-sectional view designated A-A in FIG. 5 for the trace 110, FIG. 6B illustrates the cross-sectional view designated B-B in FIG. 5 for the trace 112, and FIG. 6C illustrates the cross-sectional view designated C-C in FIG. 5 for the trace 114. As shown in FIG. 6A, the board 20 is mounted over the heatsink 50. The ground plane 90 of the board 20 contacts the top surface 100 of the heatsink 50. The ground plane 90 extends under the trace 110, with the central core 30 of dielectric material positioned between the trace 110 and the ground plane 90. The impedance of the trace 110 is a function of the dimensions (e.g., width, length, shape) of the trace 110, the Dk of the central core 30, and the thickness C_{T} of the central core 30.

In FIG. 6B, the ground plane 90 is omitted in the opening 130, which is positioned or aligned under or aligned under the trace 112. The opening 130 is similar to the openings 92 and 93 in the ground plane 90 described above. The width of the opening 130 (i.e., as measured from the left to the right on the page) is larger than the width W of the trace 112 (see FIG. 5) in FIG. 6B. The width of the opening 130 can vary. The width of the opening 130 can preferably be larger than the width W of the trace 112, but the width of the opening 130 can be the same as or smaller than the width W of the trace 112 in some cases. The omission of the ground plane 90 over the opening 130 impacts the impedance of the trace 112.

The heatsink 50 also includes the depression 140, which is also positioned under the trace 112. The depression 140 is similar to the depressions 102 and 103 described above. The width of the depression 140 (i.e., as measured from the left to the right on the page) is larger than the width W of the trace 112 (see FIG. 5) in FIG. 6B. The width of the depression 140 can be the same as the width of the opening 130 in some cases, such as that shown in FIG. 6B, but the width of the depression 140 can vary as compared to the opening 130. The width of the depression 140 can preferably be larger than the width W of the trace 112, but the width of the depression 140 can also be the same as or smaller than the width W of the trace 112 in some cases. The depth D1 of depression 140 can be formed to 1-15 mils±0.5 mils from the top surface 100 of the heatsink 50. Particular examples of the depth D1 include 1 mils, 2 mils, 3 mils, 4 mils, 5 mils, 6 mils, 7 mils, 8 mils, 9 mils, and 10 mils, and other dimensions can be used.

An air gap exists within the depression 140. In this arrangement, the top surface 141 of the depression 140 effectively acts as the ground plane 90 for the trace 112. The impedance of the trace 112 is thus a function of the dimensions of the trace 112, the Dk of the central core 30, the thickness C_{T} of the central core 30, the Dk of the air gap in the depression 140, and the thickness or depth D1 of the air gap. The effective dielectric between the trace 112 and the top surface 141 is a combination of the Dk of the central core 30, the thickness C_{T} of the central core 30, the Dk of the air gap where the ground plane 90 is omitted over the opening 130, the thickness of the ground plane 90, the Dk of the air gap in the depression 140, and the depth D1 of the air gap.

In other cases, the depression 140 can be omitted from the example shown in FIG. 6B. In this case, the effective dielectric between the trace 112 and the top surface 100 of the heatsink 150 would be a combination of the Dk of the central core 30, the thickness C_{T} of the central core 30, the Dk of the air gap in the opening 130, and the thickness of the ground plane 90.

In FIG. 6C, the ground plane 90 is omitted in the opening 132, which is positioned under or aligned under the trace 114. The omission of the ground plane 90 over the opening 132 impacts the impedance of the trace 114. The heatsink 50 also includes the depression 142, which is also positioned under the trace 114. The depth D2 of depression 142 can be formed to 1-15 mils±0.5 mils from the top surface 100 of the heatsink 50. Particular examples of the depth D2 include 1 mils, 2 mils, 3 mils, 4 mils, 5 mils, 6 mils, 7 mils, 8 mils, 9 mils, and 10 mils, and other dimensions can be used. As a comparative example, the depth D2 of the depression 142 is larger than the depth D1 of the depression 140.

An air gap exists within the depression 142. In this arrangement, the top surface 143 of the depression 142 effectively acts as the ground plane 90 for the trace 114. The impedance of the trace 114 is a function of the dimensions of the trace 114, the Dk of the central core 30, the thickness C_{T} of the central core 30, the Dk of the air gap in the depression 142, and the thickness or depth D2 of the air gap. The effective dielectric between the trace 114 and the top surface 143 is a combination of the Dk of the central core 30, the thickness C_{T} of the central core 30, the Dk of the air gap in the depression 142, and the depth D2 of the air gap. D2 can be larger than D1 in the example shown. The depth D2 can be 10 mils and the depth D1 can be 5 mils, for example, although other depths between 1-15 mils±0.5 mils or more can be relied upon for the depths D1 and D2.

Overall, the arrangement shown in FIG. 6B can result in a higher impedance of the trace 112 as compared to the trace 110 in FIG. 6A. Further, the arrangement shown in FIG. 6C can result in a higher impedance of the trace 114 as compared to the trace 112 shown in FIG. 6B. These concepts can be extended to different sizes and shapes of impedance-offset openings in ground planes, different sizes, shapes, and depths of impedance-offset depressions in heatsinks, and other variations to individually tailor the impedances of microstrip traces on RF pallets and related structures. Additionally, the traces 110, 112, and 113 can all be implemented together on the board 20.

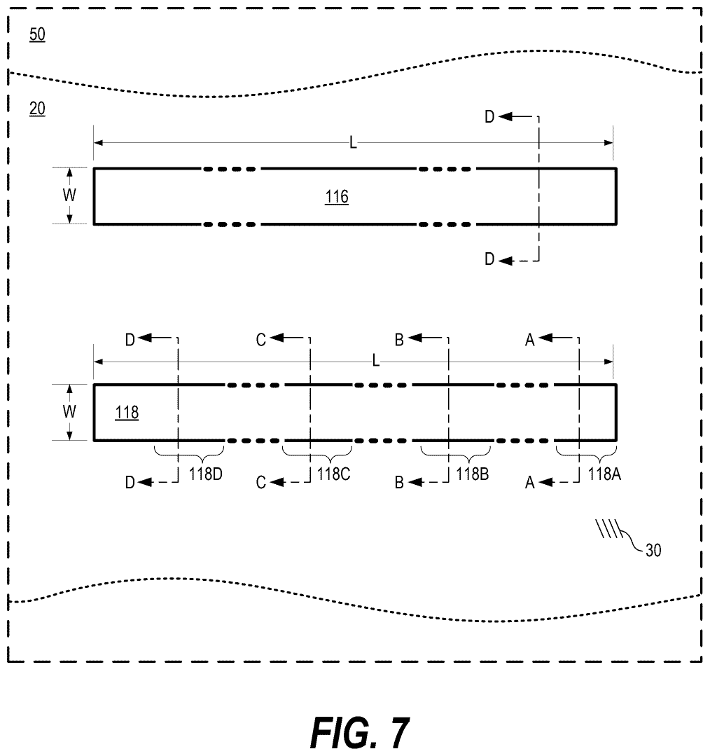

FIG. 7 illustrates microstrip traces 116 and 118. The traces 116 and 118 can be formed on the board 20, which is positioned on and over the heatsink 50. The traces 116 and 118 have the same dimensions in the example shown, including the same width W, length L, and thickness (i.e., as measured into the page). The traces 116 and 118 also have the same dimensions as the traces 110, 112, and 114 shown in FIG. 5. The central core 30 of the board 20 also has the same Dk and thickness of dielectric material for the traces 116 and 118. The central core 30 of the board 20 shown in FIG. 7 also has the same Dk and thickness of dielectric material as the example shown in FIG. 5. However, for the same signal of a common frequency, the trace 116 presents a different impedance than the traces 110, 112, and 114. The trace 118 also presents a different impedance than the traces 110, 112, 114, and 116.

FIG. 8 illustrates the cross-sectional view designated D-D in FIG. 7. In FIG. 8, the ground plane 90 is omitted over the opening region 134, which is positioned under or aligned under the trace 116. The omission of the ground plane 90 over the opening region 134 impacts the impedance of the trace 116. Additionally, the material of the central core 30 of the board 20 has been removed or recessed away, by milling, etching, or other techniques over the opening region 134, and the board 20 includes a core depression over the opening region 134. Thus, the thickness of the central core 30 is C_{T} outside the opening region 134, and the thickness of the central core 30 is C_{T1} within the opening region 134. C_{T1} within the opening region 134 is smaller than C_{T} outside the opening region 134. Thus, the central core 30 is thinner within the opening region 134 than it is outside the opening region 134. The omission of the material of the central core 30 (i.e., the thinning of the central core 30) over the opening region 134 impacts the impedance of the trace 116. The difference between C_{T} and C_{T1} can range, for example, depending on the overall thickness of the central core 30 and the desired impact on the impedance of the trace 16. As an example, for a C_{T} of 10 mils, C_{T1} can range from between 9 and 5 mils, including all increments of 0.1 mils between 9 and 5 mils. As another example, for a C_{T} of 20 mils, C_{T1} can range from between 19 and 10 mils, including all increments of 0.1 mils between 19 and 10 mils. Other C_{T} and C_{T1} dimensions can be relied upon.

The heatsink 50 also includes the depression 144 under the trace 116. The depth D3 of depression 144 can be formed to 1-15 mils±0.5 mils from the top surface 100 of the heatsink 50. An air gap exists within the depression 144. In this arrangement, the top surface 145 of the depression 144 effectively acts as the ground plane 90 for the trace 116. The impedance of the trace 116 is a function of the dimensions of the trace 116, the Dk of the central core 30, the thickness C_{T1} of the central core 30 within the opening region 134, the thickness or depth D4 of the air gap in the opening region 134, the Dk of the air gap in the depression 144, and the thickness or depth D3 of the air gap in the depression 144. The effective dielectric between the trace 116 and the top surface 145 is a combination of the Dk of the central core 30, the thickness C_{T1} of the central core 30 within the opening region 134, the thickness or depth D4 of the air gap in the opening region 134, the Dk of the air gap in the depression 144, and the thickness or depth D3 of the air gap in the depression 144. Overall, the arrangement shown in FIG. 8 can result in a higher impedance of the trace 116 as compared to the traces 110, 112, and 114 in FIGS. 6A-6C.

Referring back to FIG. 7, the microstrip trace 118 is an example of a single trace that undergoes a combination of impedance transitions. Over the length 118A of the trace 118, the board 20 and the heatsink 50 are structured according to the cross-sectional view A-A shown in FIG. 6A. Over the length 118B of the trace 118, the board 20 and the heatsink 50 are structured according to the cross-sectional view B-B shown in FIG. 6B. Over the length 118C of the trace 118, the board 20 and the heatsink 50 are structured according to the cross-sectional view C-C shown in FIG. 6C. Over the length 118D of the trace 118, the board 20 and the heatsink 50 are structured according to the cross-sectional view D-D shown in FIG. 8. Thus, the board 20 and the heatsink 50 incorporate a combination of the features shown in FIGS. 6A-6C and 8 to tailor the impedance of the trace 118.

The impedances of microstrip traces can be tailored using any combination of the features shown in FIGS. 6A-6C and 8 among the embodiments. Additionally, the board 20 can include any number of microstrips, each having an impedance that is tailored separately using a combination of the features and concepts shown in FIGS. 6A-6C and 8. The techniques described herein can be relied upon to design PCBs including microstrip traces having a relatively wide range of impedances, while also permitting the traces to be dimensioned in a suitable way to meet the power handling specifications needed for a range of applications.

The transistors in the power amplifier 40 can be formed from group III-V elemental semiconductor materials, including the III-Nitrides (Aluminum (Al), Gallium (Ga), Indium (In), and their alloys (AlGaIn) based Nitrides), Gallium Arsenide (GaAs), Indium Phosphide (InP), Indium Gallium Phosphide (InGaP), Aluminum Gallium Arsenide (AlGaAs), and compounds thereof. In other cases, the transistors in the power amplifier 40 can be formed from group IV elemental semiconductor materials, including Silicon (Si), Germanium (Ge), and compounds thereof.

The power amplifier 40 can be embodied in gallium nitride materials formed over a Si substrate, a SiC substate, or another suitable substrate. Thus, the power amplifier 40 can be embodied as power transistors formed in gallium nitride materials. The concepts described herein are not limited to the use of any particular type of substrate or semiconductor materials, however, and can be extended to use with many different types of semiconductor materials.

The power amplifier 40 can be embodied as one or more field effect transistors (FETs). Among other types of FET transistors, the power amplifier 40 can be formed as one or more high electron mobility transistors (HEMTs), pseudomorphic high-electron mobility transistors (pHEMTs), metamorphic high-electron mobility transistors (mHEMTs), and laterally diffused metal oxide semiconductor transistors (LDMOS) for use as high efficiency power amplifiers. Bipolar junction and other transistors can also be relied upon.

The power transistors described herein can be formed using a number of different semiconductor materials and semiconductor manufacturing processes. Example semiconductor materials include the group IV elemental semiconductor materials, including Si and Germanium (Ge), compounds thereof, and the group III elemental semiconductor materials, including Aluminum (Al), Gallium (Ga), and Indium (In), and compounds thereof. Semiconductor transistor amplifiers can be constructed from group III-V direct bandgap semiconductor technologies, in certain cases, as the higher bandgaps and electron mobility provided by those devices can lead to higher electron velocity and breakdown voltages, among other benefits. Thus, in some examples, the concepts can be applied to group III-V direct bandgap active semiconductor devices, such as the III-Nitrides (Aluminum (Al)-, Gallium (Ga)-, Indium (In)-, and their alloys (AlGaIn) based Nitrides), GaAs, InP, InGaP, AlGaAs, etc. devices. However, the concepts can also be applied to transistors and other active devices formed from other semiconductor materials.

The power transistors be embodied as GaN-on-Si transistors, GaN-on-SiC transistors, as well as other types of semiconductor devices. As used herein, the phrase “gallium nitride material” or GaN material refers to gallium nitride and any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}), aluminum indium gallium arsenide phosphide nitride (AlₓIn_{y}Ga_{(1-x-y)}ASₐP_{b}N_{(1-a-b)}), among others. Typically, when present, arsenic and/or phosphorous are at low concentrations (e.g., less than 5 weight percent). The term “gallium nitride” or GaN refers directly to gallium nitride, exclusive of its alloys.

The features, structures, and components described above may be combined in one or more embodiments in any suitable manner, and the features discussed in the various embodiments are interchangeable, where technically suitable. In the foregoing description, certain details are provided convey the concepts of the present disclosure. However, a person skilled in the art will appreciate that the technical solution of the present disclosure may be practiced without one or more of the specific details, or other methods, components, materials, and the like may be employed. In other instances, well-known structures, materials, or operations are not shown or described in detail to avoid obscuring aspects of the present disclosure.

Although relative terms such as “on,” “below,” “upper,” “lower,” “top,” “bottom,” “right,” and “left” may be used to describe the relative spatial relationships of certain structural features, these terms are used for convenience only, as a direction in the examples. It should be understood that if the device is turned upside down, the “upper” component will become a “lower” component. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

1. A microstrip board assembly, comprising:
a conductive heatsink; and
a microstrip board mounted to the conductive heatsink, the microstrip board comprising:
a central core of dielectric material having a dielectric constant;
a first microstrip trace on one side of the central core;
a second microstrip trace on the one side of the central core; and
a ground plane formed on another side of the central core, the ground plane extending under the second microstrip trace and comprising an impedance-offset opening under the first microstrip trace.

2. The assembly according to claim 1, wherein:
the first microstrip trace and the second microstrip trace have a same width, length, and thickness;
the first microstrip trace comprises a first impedance; and
the second microstrip trace comprises a second impedance different than the first impedance.

3. The assembly according to claim 1, wherein the central core of dielectric material has the same thickness and dielectric constant across the microstrip board.

4. The assembly according to claim 1, wherein the ground plane contacts and is electrically coupled to a top surface of the conductive heatsink.

5. The assembly according to claim 1, wherein:
the assembly comprises an effective dielectric constant between the first microstrip trace and ground that is different than the dielectric constant of the central core; and
the effective dielectric constant comprises a combination of the dielectric constant of the central core and a second dielectric constant of an air gap.

6. The assembly according to claim 1, wherein the conductive heatsink comprises an impedance-offset depression under the first microstrip trace.

7. The assembly according to claim 6, wherein the impedance-offset depression provides an air gap under the first microstrip trace.

8. The assembly according to claim 1, wherein the microstrip board comprises a core depression within the impedance-offset opening under the first microstrip trace.

9. The assembly according to claim 8, wherein the core depression provides an air gap under the first microstrip trace.

10. The assembly according to claim 1, wherein:
the ground plane comprises the impedance-offset opening under the first microstrip trace; and
the conductive heatsink comprises an impedance-offset depression under the first microstrip trace.

11. A microstrip board for microwave signals, comprising:
a central core of dielectric material having a dielectric constant;
a first microstrip trace on one side of the central core;
a second microstrip trace on the one side of the central core; and
a ground plane formed on another side of the central core, the ground plane extending under the second microstrip trace and comprising an impedance-offset opening under the first microstrip trace.

12. The microstrip board according to claim 11, wherein:
the first microstrip trace comprises a first impedance; and
the second microstrip trace comprises a second impedance different than the first impedance.

13. The microstrip board according to claim 11, wherein the central core of dielectric material has the same thickness and dielectric constant across the microstrip board.

14. The microstrip board according to claim 11, wherein the ground plane extends under a first portion of the first microstrip trace and the impedance-offset opening extends under a second portion the first microstrip trace.

15. The microstrip board according to claim 11, mounted to a conductive heatsink.

16. The microstrip board according to claim 15, wherein:
the conductive heatsink comprises an impedance-offset depression under the first microstrip trace; and
the impedance-offset depression provides an air gap under the first microstrip trace.

17. An microstrip board assembly, comprising:
a conductive heatsink; and
a microstrip board mounted to the conductive heatsink, the microstrip board comprising:
a central core of dielectric material having a dielectric constant;
a microstrip trace on one side of the central core; and
a ground plane formed on another side of the central core, the ground plane comprising an impedance-offset opening under the microstrip trace.

18. The assembly according to claim 17, wherein the ground plane contacts and is electrically coupled to a top surface of the conductive heatsink.

19. The assembly according to claim 17, wherein:
the assembly comprises an effective dielectric constant between the microstrip trace and ground that is different than the dielectric constant of the central core; and
the effective dielectric constant comprises a combination of the dielectric constant of the central core and a second dielectric constant of an air gap.

20. The assembly according to claim 17, wherein the conductive heatsink comprises an impedance-offset depression under the microstrip trace.

21. The assembly according to claim 20, wherein the impedance-offset depression provides an air gap under the microstrip trace.

22. The assembly according to claim 17, wherein the microstrip board comprises a core depression within the impedance-offset opening under the microstrip trace.

23. The assembly according to claim 22, wherein the core depression provides an air gap under the microstrip trace.

24. The assembly according to claim 17, wherein:
the ground plane comprises the impedance-offset opening under the microstrip trace; and
the conductive heatsink comprises an impedance-offset depression under the microstrip trace.
